(19) United States
(12) Patent Application Publication
(10) Pub. No.: US 2015/0008409 A1
(43) Pub. Date: Jan. 8, 2015

(54) ORGANIC LIGHT-EMITTING DEVICE, DISPLAY APPARATUS, IMAGE INFORMATION-PROCESSING APPARATUS, AND IMAGE-FORMING APPARATUS

(71) Applicant: CANON KABUSHIKI KAISHA, Tokyo (JP)

(72) Inventors: Takayuki Ito, Kawasaki-shi (JP); Naoki Yamada, Inagi-shi (JP); Yosuke Nishide, Kawasaki-shi (JP)

(21) Appl. No.: 14/320,848

(22) Filed: Jul. 1, 2014

(30) Foreign Application Priority Data
Jul. 4, 2013 (JP) 2013-140899
Jun. 27, 2014 (JP) 2014-132724

(51) Int. Cl. H01L 29/08

(52) U.S. Cl. CPC H01L 51/5275; H01L 51/5056; H01L 51/5072; G03G 15/04
USPC 257/40

(57) ABSTRACT

Provided is an organic light-emitting device having high efficiency and capable of being driven at a low voltage. An organic light-emitting device includes an anode, a cathode, and an organic compound layer including at least an emission layer between the anode and the cathode. The organic light-emitting device includes, between the anode and the emission layer, a first layer including a first organic semiconductor material and a transition metal oxide, and a second layer in contact with the first layer at an interface on a side closer to the anode and including a second organic semiconductor material. The refractive index of the first organic semiconductor material is less than 1.6. The ionization potential of the first organic semiconductor material is equal to or larger than the ionization potential of the second organic semiconductor material.

### BACKGROUND OF THE INVENTION

1. Field of the Invention

The present invention relates to an organic light-emitting device, and a display apparatus, an image information-processing apparatus, and an image-forming apparatus each using the device.

2. Description of the Related Art

An organic light-emitting device is an electronic device including a pair of electrodes formed of an anode and a cathode, and an organic compound layer placed between the pair of electrodes. An electron and a hole are injected from the pair of electrodes to produce an exciton of an organic light-emitting compound in the organic compound layer. When the exciton returns to its ground state, the organic light-emitting device emits light.

In recent years, there has been a particularly growing demand for a reduction in power consumption in a display apparatus to be built in each of various kinds of information-processing equipment. In addition, in order to satisfy the demand, an organic light-emitting device that consumes a small amount of power has been used as one member for the display apparatus. In addition, recently, an attempt has been made to improve the efficiency of the organic light-emitting device and several specific proposals have been made. Japanese Patent Application Laid-Open No. 2007-536718 discloses that a hole-transporting material and an insulative low-refractive index material are mixed to form a hole transport layer (low-refractive index layer) that itself is reduced in refractive index. In addition, Japanese Patent Application Laid-Open No. 2007-536718 discloses that the low-refractive index layer is formed as a constituent member for the organic light-emitting device to improve the emission efficiency of the organic light-emitting device. Further, Japanese Patent Application Laid-Open No. 2007-536718 describes that a void is formed in a charge-transporting layer to reduce the refractive index of a layer containing a charge-transporting material.

However, the low-refractive index layer proposed in Japanese Patent Application Laid-Open No. 2007-536718 increases the drive voltage of the device, and hence has involved a problem from the viewpoint of power consumption.

Here, a possible reason for the fact that the introduction of the low-refractive index layer increases the drive voltage is as described below. That is, in the mixed layer obtained by mixing the charge-transporting material and the insulative low-refractive index material (or the void), an interval (intermolecular distance) between the molecules of the charge-transporting material in the mixed layer tends to be large. The charge-transporting property of a layer constituting the organic light-emitting device depends on the intermolecular distance of the charge-transporting material, and hence when the intermolecular distance of the charge-transporting material enlarges, the charge-transporting property of the layer containing the charge-transporting material reduces. In addition, the presence of the insulative low-refractive index material (or the void) in the layer causes a charge trap in the charge-transporting material and reduces a charge hopping probability. Accordingly, the charge-transporting property between the molecules of the charge-transporting material remarkably reduces, and as a result, the drive voltage increases.

In addition, a reduction in refractive index of a film containing the charge-transporting material can be realized by reducing the density of the film because of a reason to be described below. However, it is difficult to suppress the increase of the drive voltage.

A Lorentz-Lorentz equation represented by the following equation [I] is available as an equation for relating a refractive index and a chemical structure.

$$\frac{{n}^{2} - 1}{{n}^{2} + 1} = \frac{[ R ]}{( \frac{M}{ρ} )} = \frac{[ R ]}{M} \times ρ \qquad [ I ]$$

(n: refractive index, [R]: molecular refraction, M: molecular weight (g/mol), p: density (g/cm³))

In general, an organic semiconductor material realizes the transfer of a charge through the hopping of a π-electron. Accordingly, an aromatic organic compound having a π-conjugated structure is used as an organic semiconductor. In addition, an organic EL material is generally solid and hence M (molecular weight) in the equation [I] is 400 or more. [R] (molecular refraction) in the equation [I], which is determined as the sum of atomic refractions constituting a molecule, is roughly 140 or more. In addition, the molecular weight and the molecular refraction are substantially in proportion to the number of atoms constituting the material. In consideration of the foregoing, in the organic semiconductor material, a rough estimate for a ratio [R]/M in the equation [I] is about 0.3. Accordingly, in consideration of the equation [I], reducing the density (π) can be said to be needed to reduce the refractive index of a layer containing the organic semiconductor material.

However, reducing the density (π) reduces the molecular density in the film, and as a result, enlarges the intermolecular distance of the compound in the film. As a result, the charge hopping probability reduces and a charge mobility reduces, which causes the increase of the voltage of the organic light-emitting device.

Another reason for the increase of the voltage due to the introduction of the low-refractive index layer is an influence by the low-dielectric constant characteristic of the low-refractive index layer represented by the following equation [II].

∈=n² [II]

(∈: dielectric constant, n: refractive index)

When the organic light-emitting device has formed therein the low-refractive index layer, in consideration of the equation [II], polarization (dielectric polarization) induced for an electric field applied in the low-refractive index layer is lower than polarization in a high-refractive index layer. Accordingly, an electric field to be applied to the low-refractive index layer (having the lower dielectric constant) is larger than that to be applied to the high-refractive index layer. Accordingly, when a voltage is applied to the organic light-emitting device having formed therein the low-refractive index layer, the electric field applied to the low-refractive index layer increases and hence a field intensity applied to a layer except the low-refractive index layer reduces. Therefore, a problem arises in that a barrier for the injection of a charge from the low-refractive index layer enlarges to cause the increase of the voltage of the device.

### SUMMARY OF THE INVENTION

The present invention has been accomplished to solve the problems and the present invention is directed to providing an organic light-emitting device having high efficiency and capable of being driven at a low voltage.

An organic light-emitting device according to one aspect of the present invention includes: an anode; a cathode; an emission layer between the anode and the cathode; a first layer including a first compound and a transition metal oxide; and a second layer including a second compound, the first layer and the second layer being formed between the anode and the emission layer, the second layer being in contact with the first layer at an interface on an anode side, in which: the first compound includes a compound having a π-conjugated structure and free of a transition metal oxide; the second compound includes a compound free of a transition metal oxide; and a refractive index of the first compound is less than 1.6.

Further features of the present invention will become apparent from the following description of exemplary embodiments with reference to the attached drawings.

### BRIEF DESCRIPTION OF THE DRAWINGS

FIGS. 1A, 1B, 1C and 1D are each a conceptual view illustrating the field intensity distribution of an organic light-emitting device of the present invention.

FIG. 2 is a schematic sectional view illustrating an example of an embodiment of an organic light-emitting device of the present invention.

FIG. 3 is a schematic perspective view illustrating an example of a light-emitting apparatus including the organic light-emitting device of the present invention.

FIG. 4 is a schematic sectional view taken along line 4-4 in FIG. 3.

FIG. 5 is a schematic sectional view taken along line 5-5 in FIG. 3.

### DESCRIPTION OF THE EMBODIMENTS

Preferred embodiments of the present invention will now be described in detail in accordance with the accompanying drawings.

(1) Organic Light-Emitting Device

An organic light-emitting device of the present invention includes: an anode; a cathode; an emission layer between the anode and the cathode; a first layer including a first compound and a transition metal oxide; and a second layer including a second compound, the first layer and the second layer being formed between the anode and the emission layer, the second layer being in contact with the first layer at an interface on an anode side, in which: the first compound is a compound having a π-conjugated structure and free of a transition metal oxide; the second compound is a compound free of a transition metal oxide; and the refractive index of the first compound is less than 1.6.

Hereinafter, the main construction of the present invention is described. It is to be noted that in the following description, the term “low refractive index” refers to the case where a refractive index at a wavelength of 550 nm is less than 1.6. In addition, in the following description, the term “refractive index” refers to a refractive index obtained by refractive index measurement in which a material in a thin film state is used as an object, a spectroscopic ellipsometry method is utilized, and a measurement wavelength is set to 550 nm. In addition, the object of the refractive index measurement is a thin film produced on an Si substrate.

(1-1) First Layer

First, the first layer is described. In the present invention, the first layer is a layer formed between the anode and the emission layer, and is a layer containing the first organic semiconductor material and the transition metal oxide.

Here, the first organic semiconductor material in the first layer is described. The first organic semiconductor material is a compound having a π-conjugated partial structure having a π-electron, and specific examples thereof include compounds such as an aromatic amine derivative, a carbazole derivative, an aromatic hydrocarbon, a siloxane derivative, and a π-conjugated polymer compound.

In the present invention, the refractive index of the first organic semiconductor material in the first layer is less than 1.6. A general organic EL material is desirably a material having a high charge mobility, and hence a film formed of the material has a high density and the refractive index of the material itself is as high as 1.7 to 1.9. The refractive index of the first organic semiconductor material is lower than that of such organic EL material and hence light extraction efficiency is improved as described later. In addition, the first organic semiconductor material has the π-conjugated structure as a partial structure. Accordingly, the material has a semiconductor characteristic derived from the partial structure and hence expresses conductivity.

Meanwhile, a long-chain alkane, an inorganic fluoride, and the like are low-refractive index materials, but are each a material free of a π-conjugated structure. Accordingly, the long-chain alkane, the inorganic fluoride, and the like are insulating materials and hence are not included in the category of the first organic semiconductor material in the present invention.

Here, the first organic semiconductor material whose refractive index is less than 1.6 is the following material in consideration of the following equation [I]: when the material is formed into a film, the density of the film is smaller than that of a film formed of the general organic EL material.

$$\frac{{n}^{2} - 1}{{n}^{2} + 1} = \frac{[ R ]}{( \frac{M}{ρ} )} = \frac{[ R ]}{M} \times ρ \qquad [ I ]$$

(n: refractive index, [R]: molecular refraction, M: molecular weight (g/mol), ρ: density (g/cm³))

Here, a preferred method of reducing the density of the film is, for example, a method involving making (at least part of) the molecular structure of a molecule constituting the film bulky. Here, a partial structure that makes the molecule itself bulky while having a π-conjugated structure is, for example, a substituent such as an alkyl group or an alkoxy group.

Here, when the alkyl group is introduced as the partial structure, specific examples of the substituent include a methyl group, an ethyl group, an n-propyl group, an isopropyl group, an n-butyl group, a t-butyl group, an s-butyl group, an octyl group, a 1-adamantyl group, and a 2-adamantyl group. Of those, an alkyl group having 4 or less carbon atoms (such as a methyl group, an ethyl group, an n-propyl group, an isopropyl group, an n-butyl group, a t-butyl group, or an s-butyl group) is preferred.

On the other hand, when the alkoxy group is introduced as the partial structure, specific examples of the substituent include a methoxy group, an ethoxy group, a propoxy group, an n-butoxy group, and an octoxy group. In the present invention, an alkoxy group having 4 or less carbon atoms (such as a methoxy group, an ethoxy group, a propoxy group, or an n-butoxy group) is preferred.

In addition, in the present invention, a siloxane structure can be further introduced into the π-conjugated partial structure of the first organic semiconductor material. A polyhedral structural body such as a silsesquioxane is particularly preferred as the siloxane structure because the polyhedral structural body is a bulky partial structure.

In addition, in the present invention, fluorine may be introduced into at least part of the partial structures constituting the compound serving as the first organic semiconductor material. The introduction of fluorine can reduce the molecular refractive index of the compound serving as the first organic semiconductor material. It is to be noted that when a substituent such as an alkyl group is introduced into the compound, fluorine is particularly preferably introduced into the substituent because a reducing effect on the refractive index of the compound itself enlarges.

As described above, the compound serving as the first organic semiconductor material has a π-conjugated partial structure, and a bulky substituent or fluorine is introduced into the partial structure. Accordingly, when the compound serving as the first organic semiconductor material is formed into a film, the formed film becomes a film having high film stability and a low density, and hence the film becomes a film having a low refractive index. It is to be noted that a specific aspect of the compound serving as the first organic semiconductor material is not limited thereto. For example, such a compound that a π-conjugated structure in the compound is provided with a twist structure such as a kink bond is available. A film formed of the compound provided with a twist structure such as a kink bond has a small density, and hence the refractive index of the formed film becomes small.

In addition, because the first organic semiconductor material has the π-conjugated partial structure, the material has a predetermined band gap. In the present invention, the band gap of the first organic semiconductor material is preferably less than 5 eV from the viewpoints of a charge-injecting characteristic and charge-transporting property. Meanwhile, in consideration of a Sellmeier equation represented by the following equation [III] representing a variance relationship between a wavelength and a refractive index, and from the following viewpoint of achieving a low refractive index in a visible light region, especially a short-wavelength region (blue region) as well, the band gap is preferably 3.0 eV or more.

$${n}^{2} = {n}_{∞}^{2} + \frac{A}{{λ}^{2} - {λ}_{0}^{2}} \qquad [ III ]$$

(n: the refractive index of a compound of interest at a specific wavelength (λ), n_{∞}: the refractive index of the compound of interest at an infrared wavelength, λ: wavelength [nm], λ₀: absorption peak wavelength [nm], A: constant)

Here, when the band gap of the compound serving as the first organic semiconductor material is 5 eV or more, the conjugation length of the π-conjugated system of the compound becomes extremely short and hence the ionization potential of the first organic semiconductor material becomes larger than the oxidation level of the transition metal oxide. Accordingly, charge transfer through the first organic semiconductor material hardly occurs.

It is to be noted that in the present invention, the number of kinds of the compounds each serving as the first organic semiconductor material in the first layer may be one, or may be two or more.

Next, the transition metal oxide in the first layer is described. When a thin film is formed only of the first organic semiconductor material, the density of the formed film (first layer) is small, which results in an increase in drive voltage of the device. Accordingly, a material that generates a carrier in the first layer, specifically the transition metal oxide needs to be incorporated into the layer. Incorporating the material that generates a carrier (transition metal oxide) into the first layer as described above can increase the carrier density of the first layer to improve the conductivity of the layer. Thus, the increase of the drive voltage of the device can be suppressed.

This is caused by the withdrawal of a π-electron of the first organic semiconductor material by the transition metal oxide, and is because of the formation of a charge-transfer complex between the first organic semiconductor material and the transition metal oxide by the withdrawal of the π-electron. It is to be noted that the withdrawal of the π-electron occurs not only through the use of the transition metal oxide but also through the use of an organic compound or inorganic compound having a withdrawing action on the π-electron. Such organic compound or inorganic compound may be used to form a charge-transfer complex between itself and the first organic semiconductor material.

As the transition metal oxide exhibiting the withdrawing action on the π-electron, a transition metal oxide having a high work function such as molybdenum oxide (MoO₃), tungsten oxide (W₂), or vanadium oxide (V₂O₅) is preferred. In particular, MoO₃, whose high vapor pressure facilitates vacuum deposition, is particularly preferred. In addition, the transition metal oxide is known to adopt multiple oxide forms and has a wide oxidation level ranging from 5.2 eV to 6.8 eV, and hence can form charge-transfer complexes with a wide variety of organic semiconductor materials. Accordingly, mixing the first organic semiconductor material and the transition metal oxide in the first layer can result in the formation of a charge-transfer complex between the first organic semiconductor material and the transition metal oxide to produce a carrier in the first layer.

The transition metal oxide of the first layer can be detected by, for example, XPS analysis. In addition, when the oxide forms a charge-transfer complex, the oxide can be detected as a result of, for example, the occurrence of broad absorption by the charge-transfer complex in a region ranging from a visible region to a near-infrared region in absorption spectrum measurement.

Thus, the first layer is a layer having a low refractive index and high conductivity. In addition, the first organic semiconductor material and the transition metal oxide are incorporated into the first layer in a state of being mixed at a molecular level, which establishes a state where a charge transfer reaction can occur between the first organic semiconductor material and the transition metal oxide. Any one of the approaches such as an application method involving using a solution containing a constituent material and a deposition method to be performed in a vacuum may be employed as a method of forming the first layer. Here, when the application method is employed, a solution containing the first organic semiconductor material and a transition metal organic complex is appropriately prepared. Meanwhile, the deposition method is particularly preferably employed because the method is hardly influenced by moisture, oxygen, an impurity, and the like. When the first layer is formed by the deposition method, a specific method therefor is, for example, a method involving codepositing the first organic semiconductor material and the transition metal oxide in a vacuum. In the present invention, the transition metal oxide in the first layer has a high refractive index and hence the mixing ratio of the transition metal oxide with respect to the first organic semiconductor material is preferably low. However, when the mixing ratio of the transition metal oxide is excessively low, the amount of the charge-transfer complex formed between the first organic semiconductor material and the transition metal oxide reduces, and hence a suppressing effect on the increase of the voltage reduces. Therefore, the mixing ratio of the transition metal oxide in the first layer is preferably from 1 vol % to 50 vol %, particularly preferably from 5 vol % to 20 vol % in terms of a volume ratio with respect to the first organic semiconductor material. In addition, the mixing ratio is preferably from 4 wt % to 90 wt % in terms of a weight ratio, though the value varies depending on the kind of the transition metal oxide. The ratio is more preferably from 18 wt % to 70 wt %. In addition, the conductivity of the first layer itself is high, and hence the thickness of the film of the first layer is not particularly limited. However, the thickness is desirably 5 nm or more, preferably 10 nm or more from the viewpoint of improving a light extraction effect. In addition, the thickness of the first layer is appropriately adjusted in consideration of, for example, optical interference.

(1-2) Second Layer

Next, the second layer is described. In the present invention, the second layer is a layer in contact with the first layer at the interface on the anode side and containing the second organic semiconductor material. That is, in the present invention, the first layer and the second layer are formed between the anode and the emission layer so as to be in contact with each other, and the first layer is a layer on the anode side and the second layer is a layer on a side closer to the emission layer.

In the present invention, the second layer has a suppressing effect on a reduction in emission efficiency of the emission layer by the first layer and an improving effect on the transportation of a hole from the first layer to the emission layer. If the first layer and the emission layer are in contact with each other, the charge-transfer complex in the first layer quenches an exciton produced by recombination in the emission layer, and hence the emission efficiency reduces. In view of the foregoing, in the present invention, the second layer containing the second organic semiconductor material is introduced into a gap between the first layer and the emission layer. Thus, the contact between the first layer and the emission layer can be prevented, and the reduction of the emission efficiency resulting from the charge-transfer complex in the first layer can be suppressed.

Specifically, a publicly known compound such as an aromatic amine derivative, a carbazole derivative, an aromatic hydrocarbon, a siloxane derivative, or a polymer compound can be used as the second organic semiconductor material in the second layer. The second organic semiconductor material preferably has a high hole mobility in order that a hole from the first layer may be efficiently injected and transported into the emission layer. Although the second organic semiconductor material may have a higher refractive index than that of the first organic semiconductor material, an organic semiconductor material having a low refractive index and a high hole mobility is particularly preferably used as the second organic semiconductor material.

In the present invention, the ionization potential of the first compound may be larger than or smaller than the ionization potential of the second compound. The ionization potential of the first organic semiconductor material is preferably equal to or larger than the ionization potential of the second organic semiconductor material. Satisfying the requirement suppresses the increase of the voltage serving as hindrance upon use of the first layer having a low refractive index to enable the reduction of the voltage of the device. Hereinafter, a reason for the foregoing is described in detail.

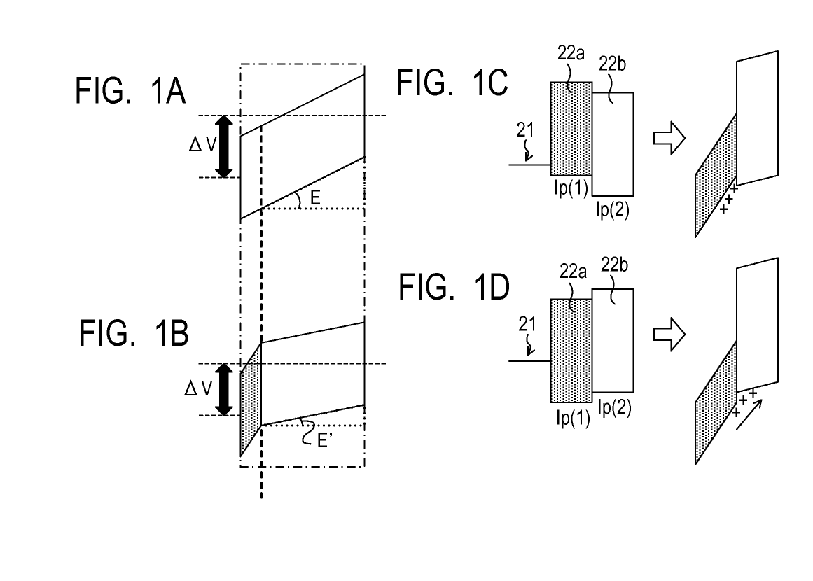

FIGS. 1A to 1D are each a conceptual view of a field intensity when a potential difference ΔV is applied to the device. FIG. 1A illustrates a field intensity distribution when a predetermined potential difference (ΔV) is applied to an organic light-emitting device free of a low-refractive index layer (first layer 22a). FIG. 1B illustrates a field intensity distribution when the predetermined potential difference (ΔV) is applied to an organic light-emitting device including the low-refractive index layer (first layer 22a). FIG. 1B shows that in the first layer 22a having a low refractive index (a low dielectric constant), dielectric polarization becomes small and hence the field intensity enlarges. As a result of such enlargement of the field intensity as described above, a field intensity E′ applied to a portion except the first layer 22a becomes smaller than a field intensity E represented in FIG. 1A. In addition, a tunnel injection barrier (triangular barrier) is formed at an interface between the first layer 22a and a second layer 22b. In the tunnel injection barrier, the following equation [IV] representing a tunnel injection probability is satisfied.

$$P ∝ exp ( - \frac{{φ}^{\frac{3}{2}}}{E} ) \qquad [ IV ]$$

(φ: injection barrier [eV] at an interface between two layers adjacent to each other of interest, E: field intensity [V/m])

As can be seen from the equation [IV], the tunnel injection probability becomes higher as the injection barrier φ becomes smaller or the field intensity E enlarges. Here, when the ionization potential of the first organic semiconductor material is equal to or larger than the ionization potential of the second organic semiconductor material, a hole injection barrier that may be taken into consideration when a hole is injected toward the emission layer can be substantially neglected as illustrated in FIG. 1D. Probably as a result of the foregoing, field intensity dependence disappears, and hence the tunnel injection probability increases and the drive voltage can be reduced. On the other hand, when the ionization potential of the first organic semiconductor material is smaller than the ionization potential of the second organic semiconductor material, an injection barrier occurs at the interface between the first layer 22a and the second layer 22b as illustrated in FIG. 1C. In addition, in such case, in particular, a voltage applied to the first layer 22a having a low refractive index enlarges. Here, when the field intensity of the emission layer reduces, an influence on the reduction of the tunnel injection probability enlarges and hence the drive voltage becomes higher than that of the related-art device free of the layer having a low refractive index (first layer 22a).

In a related-art device construction, materials to be stacked in a direction from an anode to a cathode are stacked so that their ionization potentials may enlarge in the direction. Accordingly, the related-art device construction cannot solve the problem of an increase in voltage involved in the device having the low-refractive index layer. On the other hand, when the ionization potential of the first organic semiconductor material is equal to or larger than the ionization potential of the second organic semiconductor material like the present invention, the efficiency with which a hole is injected and transported from the low-refractive index layer (first layer 22a) improves. In addition, in this case, a high electric field is applied to the low-refractive index layer (first layer 22a) having high conductivity. Accordingly, the conductivity additionally improves and hence the voltage can be reduced as compared to that of the related-art organic light-emitting device.

The thickness of the second layer needs to be such that the excitons of the emission layer do not diffuse in the first layer. Accordingly, the thickness is preferably 1 nm or more, more preferably from 5 nm to 50 nm.

In addition, the number of kinds of constituent materials for the second layer may be one (the second organic semiconductor material alone), or may be two or more (a hybrid of the second organic semiconductor material and any other material) as long as the requirement for the ionization potentials in the present invention is satisfied. The second layer may be a single layer, or may be a stack formed of multiple layers. Here, when the second layer is a stack formed of multiple layers, in a layer in contact with the first layer, the ionization potential of the first organic semiconductor material needs to be equal to or larger than the ionization potential of a constituent material for the layer in contact with the first layer.

Thus, in the present invention, the formation of two kinds of characteristic layers (the first layer and the second layer) between the anode and the emission layer enables an improvement in light extraction efficiency and a reduction in voltage, and hence can provide an organic light-emitting device that consumes a low amount of power.

(1-3) Specific Construction of Organic Light-Emitting Device

Next, an embodiment of the present invention is described with appropriate reference to the drawings. However, the present invention is not limited to the embodiment to be described below. It is to be noted that a well-known or publicly known technology in the art is applicable to a portion not particularly illustrated in the drawings or not described in the following description (description concerning the description of which is absent).

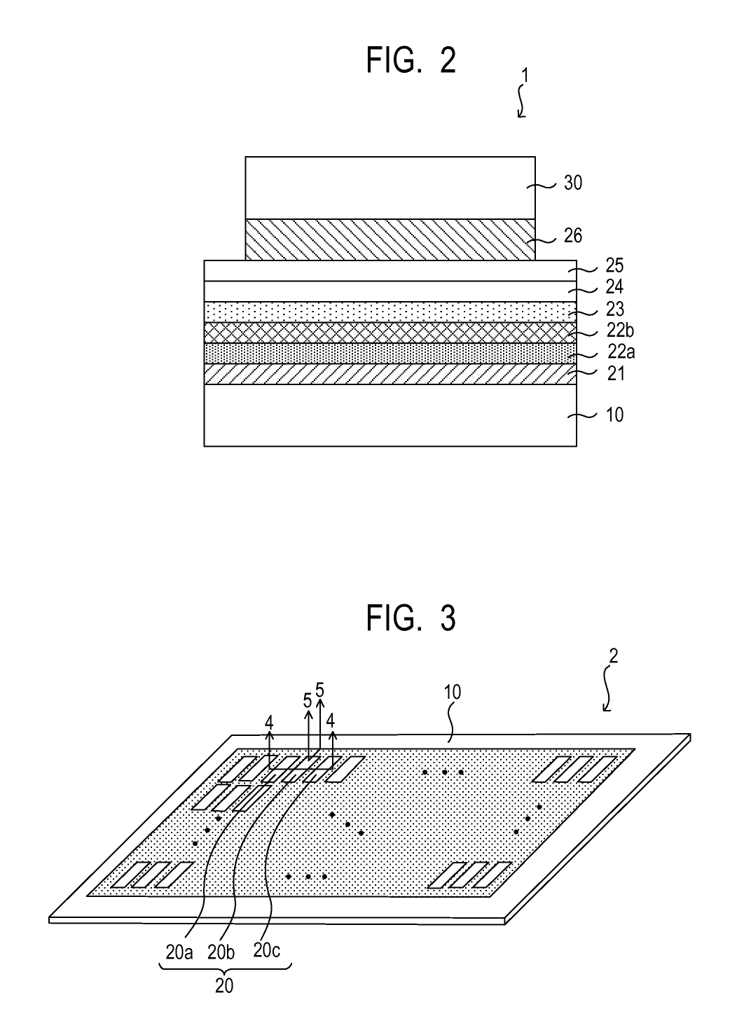

FIG. 2 is a schematic sectional view illustrating an example of the embodiment in the organic light-emitting device of the present invention. An organic light-emitting device 1 of FIG. 2 is a device obtained by sequentially stacking, on a substrate 10, an anode 21, the first layer 22a, the second layer 22b, an emission layer 23, a hole-blocking layer 24, an electron transport layer 25, and a cathode 26. In addition, in the organic light-emitting device 1 of FIG. 2, a capping layer 30 is formed on the cathode 26. In the present invention, an electrode to be formed on the substrate 10 is not necessarily limited to the anode 21. For example, the following is permitted: the cathode 26 is formed on the substrate 10, and the electron transport layer 25, the hole-blocking layer 24, the emission layer 23, the second layer 22b, the first layer 22a, and the anode 21 are sequentially formed on the cathode 26. In this case, the capping layer 30 is formed on the anode 21. Hereinafter, each constituent member for the organic light-emitting device is described. It is to be noted that the capping layer 30 may not be formed.

The substrate 10 is used as a supporting member for the organic light-emitting device. In the present invention, for example, a glass, a plastic, or a metal can be used as the substrate 10. It is to be noted that when the substrate 10 is transparent, light caused to exit from the organic light-emitting device from a side closer to the substrate 10 can be output.

A metal, an alloy, a transparent oxide conductor, or a composite thereof can be used as the anode 21. For example, there can be used: a transparent conductive material such as indium-tin oxide or indium zinc oxide; or a metal simple substance such as aluminum (Al), silver (Ag), silicon (Si), titanium (Ti), tungsten (W), or molybdenum (Mo) or an alloy obtained by mixing two or more kinds of these metal simple substances. In addition, a metal compound such as titanium nitride (TiN) can also be used. In the present invention, the anode 21 may be constituted of a single layer, or may be of a multilayer construction formed of two or more layers.

It is to be noted that in the present invention, the first layer 22a has high conductivity, and hence a constituent material for the anode 21 is not limited to a material having a large work function and a material having a small work function can also be used. In addition, when the substrate 10 and the anode 21 each have a light transmittance equal to or more than a certain value, the organic light-emitting device 1 may be of a bottom emission construction in which light is extracted from the substrate 10 side. In addition, the device may be of a top emission construction in which light is extracted from a side closer to the cathode 26 by using the anode 21 as a reflecting electrode and the cathode 26 as a light-transmissive electrode.

The first layer 22a is a hole-injecting/transporting layer containing the first organic semiconductor material and the transition metal oxide. As described above, the first layer 22a is a layer having a low refractive index and high conductivity, and hence the improvement of the emission efficiency by the improvement of the light extraction efficiency and the reduction of the drive voltage can be achieved. The first layer 22a functioning as the low-refractive index layer, which is a layer formed between the anode and the emission layer, is preferably formed so as to be in contact with the anode 21 from the viewpoints of the hole-injecting property of the layer itself and the suppression of the absorption of a plasmon by the electrode (anode 21).

The second layer 22b is a hole-injecting/transporting layer containing the second organic semiconductor material. In the present invention, the ionization potential of the second organic semiconductor material needs to be made smaller than the ionization potential of the first organic semiconductor material. Satisfying the requirement concerning the ionization potentials can solve the problem of the increase of the voltage due to the introduction of the first layer 22a as the low-refractive index layer.

The emission layer 23 is a layer containing a substance having a high light-emitting characteristic. The emission layer 23, which may be a layer formed only of the substance having a high light-emitting characteristic, is preferably a layer obtained by doping a small amount of the substance having a high light-emitting characteristic as a dopant into a host.

In this embodiment, the host for the emission layer is a compound having the largest weight ratio out of the compounds constituting the emission layer. Meanwhile, the guest for the emission layer is a compound having a smaller weight ratio than that of the host and responsible for main light emission out of the compounds constituting the emission layer. The guest is also referred to as “light-emitting material”.

An assist is a compound having a smaller weight ratio than that of the host and assisting the light emission of the guest out of the compounds constituting the emission layer. The assist is also referred to as “second host”.

Examples of the host include, but of course not limited to, a triarylamine derivative, a phenylene derivative, a fused ring aromatic compound (e.g., a naphthalene derivative, a phenanthrene derivative, a fluorene derivative, or a chrysene derivative), an organic metal complex (e.g., an organic aluminum complex such as tris(8-quinolinolato)aluminum, an organic beryllium complex, an organic iridium complex, or an organic platinum complex), and a polymer derivative such as a poly(phenylenevinylene) derivative, a poly(fluorene) derivative, a poly(phenylene) derivative, a poly(thienylenevinylene) derivative, or a poly(acetylene) derivative.

Examples of the substance having a high light-emitting characteristic (light-emitting material) include: a fluorescent light-emitting material having blue, green, or red light-emitting property such as a triarylamine derivative, a phenylene derivative, a fused ring aromatic compound (e.g., a fluoranthene derivative, a benzofluoranthene derivative, a pyrene derivative, a chrysene derivative, or a derivative obtained by substitution thereof with a diarylamine), or a stilbene derivative; and a phosphorescent light-emitting material having blue, green, or red light-emitting property such as an organic metal complex (e.g., an organic iridium complex, an organic platinum complex, or a rare earth metal complex). In the present invention, the content of the substance having a high light-emitting characteristic in the emission layer 23 is preferably 0.1 mass % or more and 30 mass % or less, more preferably 0.5 mass % or more and 10 mass % or less with reference to the total amount of the emission layer.

It is to be noted that as illustrated in the organic light-emitting device 1 of FIG. 2, the hole-blocking layer 24 may be formed so that a hole may not transfer from the emission layer 23 to the cathode 26. A constituent material for the electron transport layer 25 to be described next can be selected as a constituent material for the hole-blocking layer 24.

The electron transport layer 25 is a layer for efficiently injecting and transporting an electron injected from the cathode 26 into the emission layer 23. An electron-injecting material or electron-transporting material in the electron transport layer 25 is appropriately selected in consideration of, for example, a balance with the hole mobility of a hole-injecting material or hole-transporting material. A material having electron injecting performance or electron transporting performance is exemplified by, but of course not limited to, a fused ring aromatic compound (e.g., a naphthalene derivative, a phenanthrene derivative, a fluorene derivative, or a chrysene derivative), an oxadiazole derivative, an oxazole derivative, a pyrazine derivative, a triazole derivative, a triazine derivative, a quinoline derivative, a quinoxaline derivative, a phenanthroline derivative, and an organic aluminum complex.

In the present invention, for the purpose of efficiently injecting and transporting an electron injected from the cathode 26 into the emission layer 23, an electron-injecting layer may be formed between the electron transport layer 25 and the cathode 26 so as to be in contact with the cathode 26. A constituent material for the electron-injecting layer is, for example, a mixed material of an electron-transporting material and an alkali metal (such as cesium or lithium) or an alkali metal compound (such as cesium carbonate, lithium carbonate, or cesium fluoride). A codeposited film of the mixed material is formed upon formation of the electron-injecting layer but a method of forming the layer is not limited thereto. In addition, as the electron-injecting layer to be introduced between the electron transport layer 25 and the cathode 26, a layer having a thickness of from 0.5 nm to 2 nm may be formed of cesium carbonate, lithium carbonate, or a fluoride such as lithium fluoride, magnesium fluoride, or barium fluoride.

A constituent material for the cathode 26 is, for example, an alkali metal such as lithium, an alkaline earth metal such as calcium, or a metal simple substance such as aluminum, titanium, manganese, silver, lead, or chromium. Alternatively, an alloy obtained by combining multiple kinds of those metal simples substances can also be used. For example, magnesium-silver, aluminum-lithium, aluminum-magnesium, aluminum-molybdenum, or the like can be used. A metal oxide such as indium tin oxide (ITO) can also be utilized. One kind of those electrode substances may be used alone, or multiple kinds thereof may be used in combination. In addition, the cathode may be constituted of a single layer, or may be of a multilayer construction formed of two or more layers.

The capping layer 30 is used as a member for adjusting optical interference in a top emission-type organic light-emitting device in which emitted light is extracted from the cathode 26 side. Accordingly, the layer is not necessarily needed to be formed in a bottom emission-type organic light-emitting device in which emitted light is extracted from the substrate 10 side. A constituent material for the capping layer 30 is, for example, an inorganic material such as silicon oxide, silicon nitride, indium tin oxide, or indium zinc oxide, or an organic material. In addition, the capping layer 30 can adjust the reflectance and transmittance of the cathode 26. The thickness of the capping layer 30, which can be appropriately set depending on purposes, is preferably 50 nm or more and 300 nm or less.

In addition, the organic light-emitting device of the present invention may be sealed with a glass or a metal. The organic light-emitting device 1 of FIG. 2 may be sealed with a sealing film formed of an inorganic material on the capping layer 30. A constituent material for the sealing film to be formed on the capping layer 30 is specifically, for example, an inorganic material such as silicon nitride, silicon oxide, silicon oxynitride, or aluminum oxide. It is to be noted that in the present invention, the sealing film may be constituted of one layer, or may be constituted of two or more layers. In addition, when the sealing film is formed, its thickness is preferably 100 nm or more and 10 μm or less.

In the organic light-emitting device of the present invention, as a method of forming constituent members including the first layer 22a and the second layer 22b, in general, there are given, for example: a dry film formation method such as a vacuum deposition method, an ionized vapor deposition method, a sputtering method, and a film formation method involving using plasma; and a wet film formation method typified by a known application method involving using an appropriate solvent (such as spin coating, dipping, a casting method, an LB method, or an ink jet method).

(2) Applications of Organic Light-Emitting Device

The organic light-emitting device of the present invention can be used as a constituent member for a display apparatus or lighting apparatus. In addition, the device finds use in applications such as an exposure light source for an electrophotographic image-forming apparatus, a backlight for a liquid crystal display apparatus, and lighting. It is to be noted that when the organic light-emitting device is used as a constituent member for any such apparatus as listed above, the apparatus may further include a color filter.

A display apparatus of the present invention includes a display portion including multiple pixels, and each of the pixels is provided with the organic light-emitting device of the present invention. In addition, the pixel includes not only the organic light-emitting device of the present invention but also an active device connected to the organic light-emitting device of the present invention. An example of the active device is a switching device for controlling an emission luminance and an example of the switching device is a TFT device. It is to be noted that the TFT device is provided on the insulative surface of the substrate (the surface of a base material constituting the substrate).

In the display apparatus of the present invention, an electrode (an anode or a cathode) to be formed on a side closer to the substrate of the organic light-emitting device is electrically connected to the drain electrode or source electrode of the TFT device. The display apparatus of the present invention can be used as an image display apparatus for a personal computer (PC).

The display apparatus of the present invention may be an image information-processing apparatus that includes, in addition to the above-mentioned members, an input portion for inputting image information from an area CCD, a linear CCD, or a memory card, and that is configured to display the input image to the display portion.

In addition, a display portion included in an image information-processing apparatus or an image-forming apparatus may have a touch panel function. Further, the display apparatus of the present invention may be used for a display portion of a multifunction printer.

A lighting apparatus is an apparatus for lighting, for example, the inside of a room. The lighting apparatus according to this embodiment includes the organic light-emitting device according to the present invention. When the lighting apparatus includes multiple organic light-emitting devices, any one of the multiple organic light-emitting devices has only to be the organic light-emitting device of the present invention. In that case, the organic light-emitting device of the present invention may be a device that emits light having a wavelength corresponding to any one of a white color, a neutral white color, a blue color, and a red color. In the present invention, the lighting apparatus emits at least two kinds of light having different emission wavelengths. A specific method of causing the apparatus to emit the two kinds of light having different emission wavelengths is, for example, a method involving incorporating multiple kinds of light-emitting materials having different emission wavelengths into the emission layer of the organic light-emitting device. Another method is, for example, a method involving using a stack, which is obtained by stacking multiple thin films formed of light-emitting materials having different emission wavelengths, as the emission layer. Thus, multiple kinds of light having different wavelengths are emitted from the emission layer (stacked layer corresponding to the emission layer), and the multiple kinds of light emitted from the emission layer (stacked layer corresponding to the emission layer) serve as illumination light. The color of the illumination light is preferably a white color.

The lighting apparatus of the present invention is, for example, a lighting apparatus including the organic light-emitting device of the present invention and an AC/DC converter circuit connected to the organic light-emitting device of the present invention. It is to be noted that the lighting apparatus of the present invention may further include a color filter. In addition, the AC/DC converter circuit included in the lighting apparatus of the present invention is a circuit for converting an AC voltage into a DC voltage, and is a circuit for supplying a drive voltage to the organic light-emitting device.

An image-forming apparatus of the present invention includes: a photosensitive member; a charging portion for charging the surface of the photosensitive member; an exposing portion for exposing the photosensitive member; and a developing unit for developing an electrostatic latent image formed on the surface of the photosensitive member. Here, the exposing unit to be provided in the image-forming apparatus uses the organic light-emitting device of the present invention. The exposing unit is, for example, an exposing machine including the organic light-emitting device of the present invention. The multiple organic light-emitting devices of the exposing machine may be arrayed to form a line, or the exposing machine may be of such a form that the entirety of its exposure surface emits light.

Hereinafter, the display apparatus of the present invention is described with reference to the drawings. It is to be noted that the embodiments of the display apparatus of the present invention are not limited to embodiments described below. In addition, a well-known technology or publicly known technology in the art is applicable to a portion not particularly illustrated in the drawings or not particularly described in the following description.

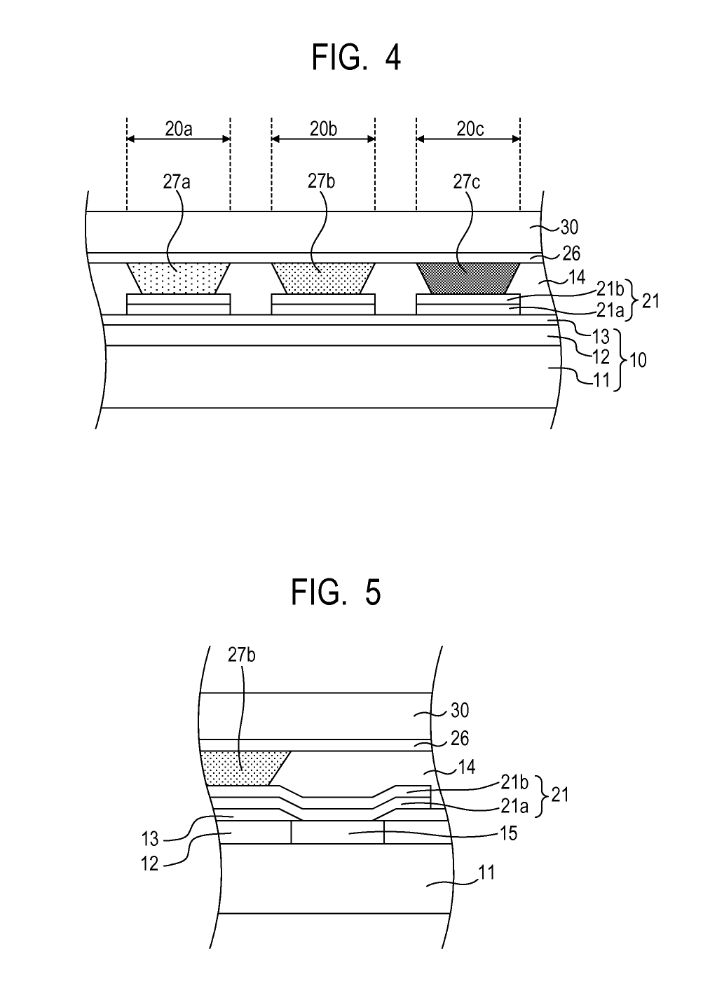

FIG. 3 is a perspective view illustrating an example of the embodiment of the display apparatus of the present invention. In addition, FIG. 4 is a schematic sectional view taken along line 4-4 of the display apparatus of FIG. 3, and FIG. 5 is a schematic sectional view taken along line 5-5 of the display apparatus of FIG. 3.

A display apparatus 2 of FIG. 3 includes pixels 20 each formed of three kinds of sub-pixels (20a, 20b, 20c) on the substrate 10, and each sub-pixel (20a, 20b, 20c) is provided with the organic light-emitting device of the present invention. In the display apparatus 2 of FIG. 3, the respective pixels 20 are placed in a matrix manner to form a display region 3. It is to be noted that in the display apparatus 2 of FIG. 3, the pixel 20 means a region corresponding to the light-emitting region of one light-emitting device. In the display apparatus 2 of FIG. 3, the organic light-emitting device is used as a light-emitting device and an organic light-emitting device that emits light having a specific color is placed in each sub-pixel (20a, 20b, 20c).

The emission color of each organic light-emitting device included in the display apparatus 2 of FIG. 3 is, for example, a red color, a green color, or a blue color, but is not limited thereto and may be, for example, a white color, a yellow color, or a cyan color instead. In addition, each pixel 20 of the display apparatus 2 of FIG. 3 is a pixel unit formed of the multiple sub-pixels (20a, 20b, 20c) having different emission colors. Here, the pixel unit is a minimum unit that enables the emission of light having a desired color through the light emission or color mixing of the respective sub-pixels. In addition, the display apparatus 2 of FIG. 3 can be used as a light-emitting apparatus. In addition, the array mode of the pixels included in the display apparatus 2 of FIG. 3 is not limited to such matrix shape as illustrated in FIG. 3, and for example, multiple pixels having the same emission color may be arrayed in a one-dimensional direction in order that the pixels may be utilized as an exposing machine for a print head.

Each sub-pixel (20a, 20b, 20c) of the display apparatus 2 of FIG. 3 includes, for example, the anode 21 formed on the substrate 10, an organic compound layer (27a, 27b, 27c) formed on the anode 21, and the cathode 26 formed on the emission layer as illustrated in FIG. 4. It is to be noted that the organic light-emitting devices of the respective sub-pixels each include the anode 21, the organic compound layer (27a, 27b, 27c), and the cathode 26.

Hereinafter, each constituent member for the display apparatus 2 of FIG. 3 is described.

As illustrated in FIG. 4 and FIG. 5, the substrate 10 on which the multiple pixels 20 are formed includes a base material 11, a transistor layer 12 formed on the base material 11, and a first insulating layer 13 formed on the transistor layer 12.

Examples of the base material 11 include a glass substrate, a semiconductor substrate, and a metal substrate, and a flexible base material may be used.

The transistor layer 12 formed between the base material 11 and the anode 21 serving as a first electrode is a member placed for supplying a current to each organic light-emitting device, and is electrically connected to the anode 21 (first electrode) through a contact portion 15 in FIG. 5. It is to be noted that the contact portion 15 illustrated in FIG. 5 is part of the transistor layer 12 and is the source electrode or drain electrode of a transistor. The contact portion 15 is not covered with the first insulating layer 13, and the anode 21 (first electrode) and the source electrode or the drain electrode are electrically connected to each other. The transistor layer 12 may be formed of, for example, a polysilicon or an amorphous silicon.

The first insulating layer 13 is a layer formed for covering the transistor layer 12 to planarize unevenness produced upon formation of the transistor layer 12. It is to be noted that as illustrated in FIG. 5, the first insulating layer 13 is provided with an opening for electrically connecting the contact portion 15 and the anode 21 in at least part of a region where the contact portion 15 is formed. An inorganic insulating layer made of silicon nitride, silicon oxide, silicon oxynitride, or the like can be used as a constituent material for the first insulating layer 13. The thickness of the first insulating layer 13 is preferably 100 nm or more and 1 μm or less. In addition, a second insulating layer 14 (pixel-separating film) to be described later may be produced simultaneously with the formation of the first insulating layer 13.

The second insulating layer 14 is formed between the respective sub-pixels (20a, 20b, 20c) included in the display region 3 and adjacent to each other. The second insulating layer 14 is a member also called a pixel-separating film because the member divides the respective sub-pixels (20a, 20b, 20c) in a sub-pixel unit. It is to be noted that the second insulating layer 14 is a member formed on the contact portion 15 so as to cover the anode 21 formed on the contact portion 15 as illustrated in FIG. 5. A resin material such as polyimide or acryl, an inorganic material such as silicon nitride, or the like can be used as a constituent material for the second insulating layer 14. Here, the second insulating layer 14 is preferably constructed of the resin material so as to planarize the surface unevenness produced upon provision of the transistor layer 12. In this regard, however, the constituent material for the second insulating layer 14 is not limited to the resin material and the inorganic material may be used. When the inorganic material is used as the constituent material for the second insulating layer 14, the second insulating layer 14 is preferably constructed as follows: its surface is abraded so as to be flat. When the second insulating layer 14 is formed of the resin material, the thickness of the second insulating layer 14 is preferably 300 nm or more and 10 μm or less. In addition, when the second insulating layer 14 is formed of the inorganic material, the thickness is preferably 100 nm or more and 1 μm or less.

In the display apparatus 2 of FIG. 3, the anode formed on the substrate 10 is a stacked electrode obtained by stacking a reflecting member 21a and an electrode member 21b in the stated order. That is, in the display apparatus 2 of FIG. 3, the anode 21 is a reflecting electrode and hence the display apparatus 2 of FIG. 3 is an apparatus including the top emission-type organic light-emitting device in which light is caused to exit from the cathode 26 as a second electrode formed on a side opposite to the substrate 10.

The reflecting member 21a that constitutes the anode 21 and reflects light caused to exit from the emission layer in each organic compound layer (27a, 27b, 27c) is formed by using a highly reflective material such as Al, an Al alloy such as AlNd, or an Ag alloy. The thickness of the reflecting member 21a is preferably 50 nm or more and 200 nm or less. It is to be noted that the reflecting member 21a is connected to the transistor layer 12 through a contact hole (not shown).

A metal having a high work function such as Mo or W can be used in the electrode member 21b constituting the anode 21. An oxide of a metal having a high work function can also be used. Further, a transparent conductive oxide such as an indium tin oxide or an indium zinc oxide can be used. It is to be noted that in the organic light-emitting device of the present invention, the electrode member 21b is not necessarily needed to be formed because a metal having a low work function can also be used as the constituent material for the anode 21.

The constituent material for the anode 21, which is an electrode formed on the substrate 10 and is included in the top emission-type organic light-emitting device, and a specific construction thereof have been described above. Meanwhile, the display apparatus 2 of FIG. 3 may be a display apparatus having the bottom emission-type organic light-emitting device. In this case, an electrode thin film formed of a transparent conductive oxide such as an indium tin oxide or an indium zinc oxide is formed as the anode 21 constituting the display apparatus.

The organic compound layer (27a, 27b, 27c) includes at least the first layer 22a, second layer 22b, and emission layer 23 in FIG. 2. It is to be noted that the emission layers in the respective organic compound layers (27a, 27b, 27c) differ from one another in color of light to be caused to exit depending on the kind of sub-pixel. In the display apparatus 2 of FIG. 3, the first layer as the low-refractive index layer and the second layer formed on the first layer so as to be in contact with the first layer are formed on the anode 21 (first electrode). Accordingly, the organic light-emitting device included in the display apparatus of the present invention is an organic light-emitting device that is driven at a low voltage and has high efficiency. In addition, each organic compound layer (27a, 27b, 27c) has an emission layer that emits red light, an emission layer that emits green light, or an emission layer that emits blue light, and each emission layer is patterned into a desired shape in correspondence with a pixel that emits red light, green light, or blue light. In addition, the layers in each organic compound layer (27a, 27b, 27c) are not limited to the first layer, the second layer, and the emission layer, and the layer may have one or two or more charge-injecting/transporting layers such as a hole transport layer and an electron transport layer in addition to the layers. It is to be noted that the charge-injecting/transporting layer except the first layer, the second layer, and the emission layer (the hole transport layer or the electron transport layer), which is included in each organic compound layer (27a, 27b, 27c), may be formed so as to correspond to a region where each sub-pixel (20a, 20b, 20c) is placed, or may be formed across multiple pixels. A combination of such formation methods is also permitted.

In the display apparatus 2 of FIG. 3, the anodes each serving as the first electrode are divided in a sub-pixel unit by the second insulating layer 14 (device-separating film). Meanwhile, the cathode 26 serving as the second electrode may be formed as an electrode common to all pixels (sub-pixels), or may be patterned into a desired shape as an electrode divided for each pixel (or each sub-pixel). Although the second insulating layer 14 is preferably formed in the display apparatus 2 of FIG. 3 so that no short circuit may be formed between the anode 21 and the cathode 26, an insulating member as a member different from the second insulating layer 14 may be formed so as to cover an end portion of the anode 21.

The display apparatus of the present invention may include a capping layer 30 formed of one of an organic material and an inorganic material on the cathode 26 as illustrated in FIG. 3. Appropriately adjusting the thickness of the capping layer 30 can additionally improve the emission efficiency of each organic light-emitting device included in the display apparatus because the adjustment enables efficient utilization of an optical interference effect. In addition, in the display apparatus 2 of FIG. 3, a sealing glass (not shown) may be mounted on the capping layer 30 to seal the organic light-emitting devices in order that the intrusion of moisture or oxygen may be prevented.

The display apparatus of the present invention may be used as a light-emitting apparatus in an image-forming apparatus such as a laser beam printer. The term “image-forming apparatus” as used herein more specifically refers to an apparatus including: a photosensitive member on which a latent image is formed by the light-emitting apparatus; and a charging unit for charging the photosensitive member. In addition, as described in the foregoing, the display apparatus of the present invention may include multiple organic light-emitting devices that emit light beams having different colors. In this case, the apparatus can be used in a display or electronic viewfinder for an imaging apparatus such as a digital camera or digital camcorder including an imaging device such as a CMOS sensor. Alternatively, the apparatus can be used in a display for an image-forming apparatus, or a display for a personal digital assistant such as a cellular phone or a smart phone. In addition, the light-emitting apparatus of the present invention may be of a construction including: multiple organic light-emitting devices each emitting light having a single color; and red, green, and blue color filters.

An organic light-emitting device was produced according to a method described in Examples or Comparative Examples to be described below. Here, compounds used in Examples and Comparative Examples to be described below are shown below.

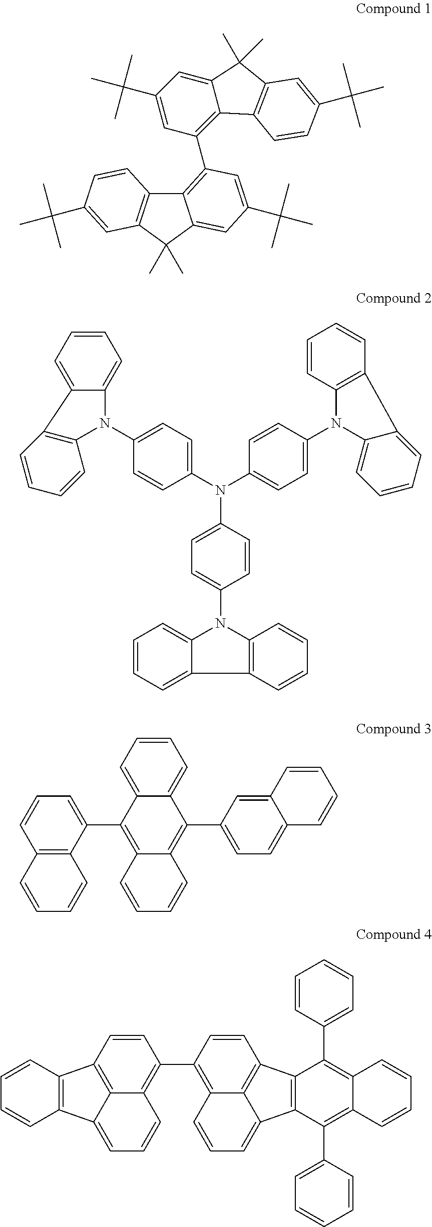

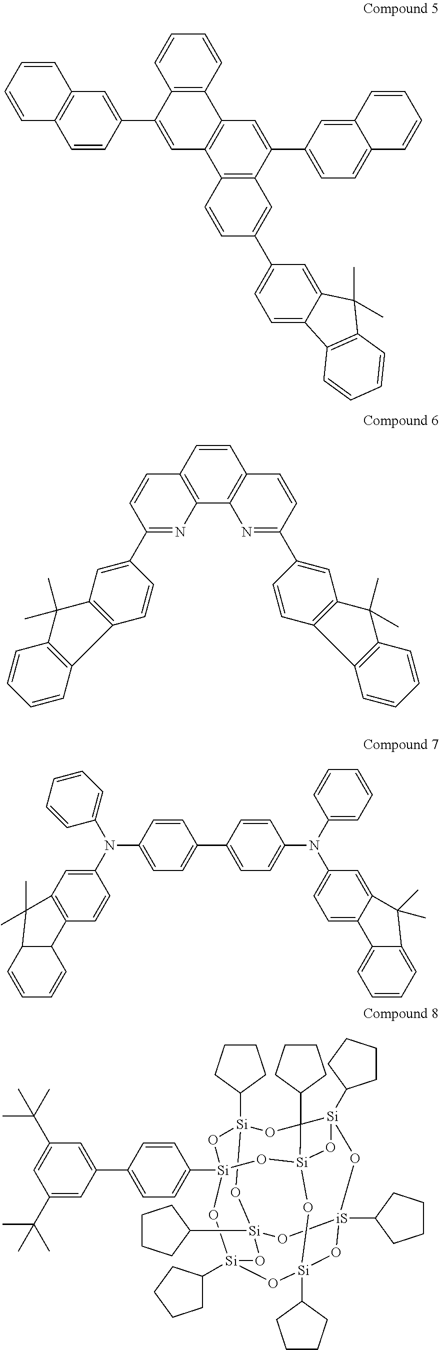

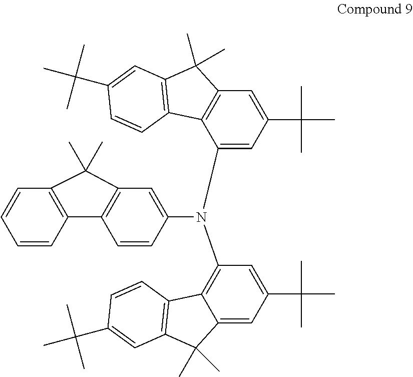 [SMILES: CC(C)(C)c1ccc2c(c1)C(C)(C)c1cc(C(C)(C)C)cc(N(c3ccc4c(c3)C(C)(C)c3ccccc3-4)c3cc(C(C)(C)C)cc4c3-c3ccc(C(C)(C)C)cc3C4(C)C)c1-2]

It is to be noted that the nine kinds of compounds were measured and evaluated for their physical properties (a refractive index, an ionization potential, and a band gap) in advance by methods to be described below.

(A) Refractive Index

Measurement was performed by an ellipsometry method. It is to be noted that a refractive index used in physical property evaluation is a refractive index at a wavelength of 550 nm.

(B) Ionization Potential

The ionization potential of a deposited film formed by a vacuum deposition method on an Si substrate to have a thickness of 30 nm was measured with an atmospheric spectrometer (AC-3 manufactured by RIKEN KEIKI Co., Ltd.).

(C) Band Gap

The sample (deposited film) used in the measurement and evaluation of the ionization potential was used. The ultraviolet absorption spectrum of the deposited film was measured. Then, a band gap was estimated from an absorption edge of the resultant spectrum.

Table 1 below shows the results of the measurement and evaluation of the physical properties of the compounds used in Examples and Comparative Examples.

TABLE 1

| | | | Ionization | Band |
|---|---|---|---|---|
| | | Refractive | potential | gap |
| | Compound | index | (eV) | (eV) |
| First organic | Compound 1 | 1.58 | 6.4 | 3.9 |
| semiconductor | Compound 8 | 1.5 | 6.8 | 4.3 |
| material | Compound 9 | 1.6 | 5.4 | 3.2 |
| | Compound 7 | 1.77 | 5.4 | 3.1 |
| Second organic | Compound 2 | 1.83 | 5.9 | 3.3 |
| semiconductor | | | | |
| material | | | | |
| Emission layer (host) | Compound 3 | 1.82 | 6 | 3 |
| Hole-blocking layer | Compound 5 | 1.8 | 6.1 | 3.1 |
| Electron transport | Compound 6 | 1.82 | 5.9 | 3 |
| layer | | | | |

Methods of synthesizing part of compounds each serving as the first organic semiconductor material are described below.

### Synthesis Example 1

### Synthesis of Compound 1

Compound 1 was synthesized according to the following synthesis scheme.

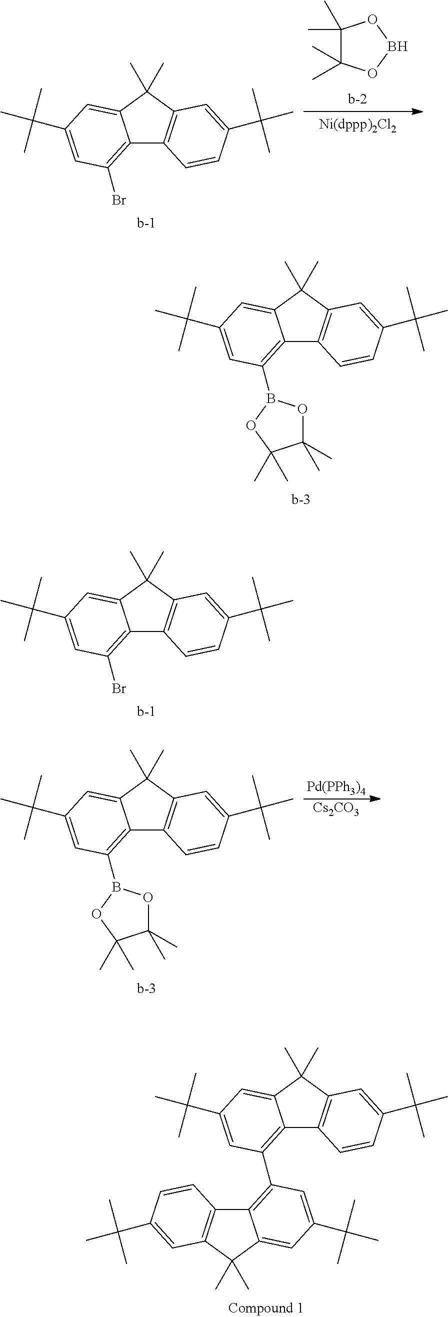

The details of the synthesis scheme are described below.

(1) Synthesis of Compound b-3

The following reagents and solvents were loaded into a 100-ml three-necked flask.

Compound b-1: 10.3 g (34.3 mmol)
[1,1′-Bis(diphenylphosphino)propane]dichloronickel: 1.88 g (3.43 mmol)
Compound b-2: 9.9 ml (68.5 mmol)

### Toluene: 200 ml

### Triethylamine: 30 ml

Next, in a nitrogen atmosphere, the temperature of the reaction solution was increased to 90° C. and then the solution was stirred at the temperature (90° C.) for 6 hours. After the completion of the reaction, 200 ml of water were added to the resultant, and then the organic layer was extracted with toluene and dried with anhydrous sodium sulfate. Next, a crude product obtained by concentrating the organic layer under reduced pressure was purified by silica gel column chromatography (eluent: a mixed solvent of toluene and heptane) to provide 12.2 g (yield: 82%) of Compound b-3 as a white crystal.

(2) Synthesis of Compound 1

The following reagents and solvents were loaded into a 100-ml three-necked flask.

Compound b-1: 2.50 g (6.50 mmol)
Compound b-3: 3.65 g (8.43 mmol)
Cesium carbonate: 6.35 g

### Toluene: 30 ml

### Ethanol: 10 ml

### Water: 30 ml

Next, in a nitrogen atmosphere, 376 mg of tetrakis(triphenylphosphine)palladium(0) were added while the reaction solution was stirred at room temperature. Next, the temperature of the reaction solution was increased to 80° C. and then the solution was stirred at the temperature (80° C.) for 5 hours. After the completion of the reaction, the organic layer was extracted with toluene and dried with anhydrous sodium sulfate. Next, a crude product obtained by concentrating the organic layer under reduced pressure was purified by silica gel column chromatography (eluent: a mixed solvent of toluene and heptane) to provide 3.70 g (yield: 93%) of Compound 1 as a white crystal.

Mass spectrometry confirmed 611 as the M⁺ of Compound 1. In addition, ¹H-NMR measurement confirmed the structure of Compound 1.

¹H-NMR (CDCl₃, 400 MHz) σ (ppm): 7.51 (s, 2H), 7.34-7.33 (m, 4H), 6.86 (d, 2H), 6.36 (s, 2H), 1.56 (s, 6H), 1.52 (s, 6H), 1.41 (s, 18H), 1.27 (s, 18H)

### Synthesis Example 2

### Synthesis of Compound 8

Compound 8 was synthesized according to the following synthesis scheme.

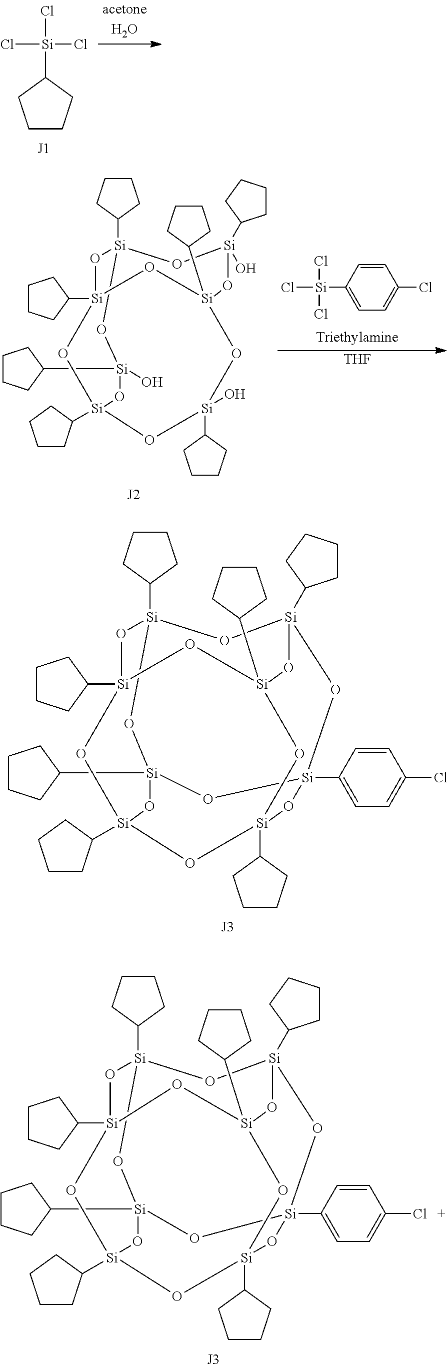 [SMILES: Cl[Si](Cl)(Cl)C1CCCC1 ; O[Si]1(C2CCCC2)O[Si]2(C3CCCC3)O[Si](O)(C3CCCC3)O[Si]3(C4CCCC4)O[Si](O)(C4CCCC4)O[Si](C4CCCC4)(O1)O[Si](C1CCCC1)(O2)O3 ; Clc1ccc([Si](Cl)(Cl)Cl)cc1 ; Clc1ccc([Si]23O[Si]4(C5CCCC5)O[Si]5(C6CCCC6)O[Si](C6CCCC6)(O2)O[Si]2(C6CCCC6)O[Si](C6CCCC6)(O3)O[Si](C3CCCC3)(O4)O[Si](C3CCCC3)(O5)O2)cc1 ; "THF" ; Clc1ccc([Si]23O[Si]4(C5CCCC5)O[Si]5(C6CCCC6)O[Si](C6CCCC6)(O2)O[Si]2(C6CCCC6)O[Si](C6CCCC6)(O3)O[Si](C3CCCC3)(O4)O[Si](C3CCCC3)(O5)O2)cc1]

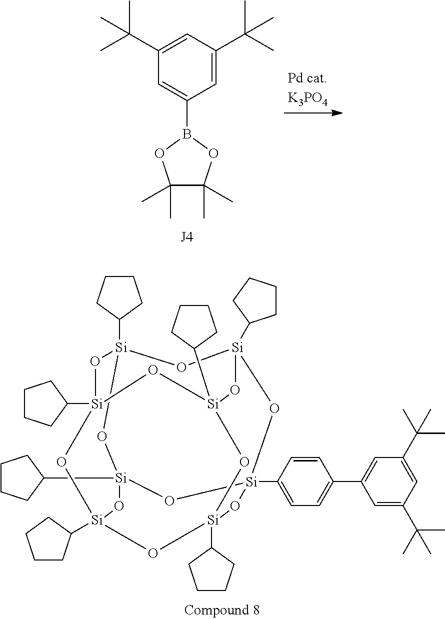 [SMILES: CC(C)(C)c1cc(B2OC(C)(C)C(C)(C)O2)cc(C(C)(C)C)c1 ; CC(C)(C)c1cc(-c2ccc([Si]34O[Si]5(C6CCCC6)O[Si]6(C7CCCC7)O[Si](C7CCCC7)(O3)O[Si]3(C7CCCC7)O[Si](C7CCCC7)(O4)O[Si](C4CCCC4)(O5)O[Si](C4CCCC4)(O6)O3)cc2)cc(C(C)(C)C)c1]

The details of the synthesis scheme are described below.

(1) Synthesis of Compound J2

The following reagent and solvent were loaded into a reaction vessel.

Compound J1: 25 ml (150 mmol)

### Acetone: 600 ml

Next, 170 ml of distilled water were dropped into the reaction solution. Next, the reaction solution was heated to 70° C. and the solution was stirred at the temperature (70° C.) for 3 days. After the completion of the reaction, the suspension was filtered and washed with acetone. After that, pyridine was charged into the resultant to provide a pyridine solution. Next, the pyridine solution was brought into an acidic condition to be caused to produce a crystal. Next, the crystal was subjected to Soxhlet extraction with diethyl ether and chloroform to provide 6.3 g (yield: 33%) of Compound J2 as a white solid.

(2) Synthesis of Compound J3

The following reagents and solvent were loaded into a reaction vessel.

Compound J2: 3.1 g (3.5 mmol)
Triethylamine: 1.0 g (10 mmol)

### THF: 18 ml

Next, 0.93 g (3.8 mmol) of trichloro(4-chlorophenyl)silane was dropped into the reaction solution. Next, the reaction solution was stirred at room temperature for 12 hours and then the produced solid was collected by filtration. Next, the solid collected by filtration was purified by silica gel column chromatography (eluent: heptanes/chloroform=4/1) to provide 1.4 g (yield: 39%) of Compound J3 as a white solid.

(3) Synthesis of Compound 8

The following reagents and solvent were loaded into a reaction vessel.

Palladium acetate: 26 mg (0.12 mmol)
x-Phos: 160 mg (0.35 mmol)

### Toluene: 3 ml

Next, the reaction solution was stirred at room temperature for 15 minutes and then the following reagents and solvent were loaded into the reaction solution.

Compound J3: 400 mg (1.3 mmol)
Compound J4: 1.2 g (1.2 mmol)
Potassium phosphate: 980 mg (4.6 mmol)

### Water: 0.53 ml

Next, the reaction solution was heated to 95° C. and the solution was stirred at the temperature (95° C.) for hours. After the completion of the reaction, the reaction solution was cooled and then 20 ml of heptane were added to the solution. The mixture was purified by silica gel column chromatography (eluent: heptanes/chloroform=10/1) to provide 730 mg (yield: 54%) of Compound 8 as a white solid.

Mass spectrometry based on LC-MS involving using a micromass ZQ manufactured by Waters confirmed 1,166 as the M⁺ of Compound 8.

### Example 1

The organic light-emitting device illustrated in FIG. 2 was produced by a method to be described below. It is to be noted that in this example, Compound 1 used as the first organic semiconductor material has a lower refractive index and a larger ionization potential than those of Compound 2 as the second organic semiconductor material.

Indium tin oxide (ITO) was formed into a film on a glass substrate (the substrate 10) by a sputtering method to form the anode 21. At this time, the thickness of the anode 21 was set to 120 nm. Next, the substrate 10 with the anode 21 formed thereon was subjected to ultrasonic washing sequentially with acetone and isopropyl alcohol (IPA) and then subjected to boiling washing with IPA, followed by drying. Further, the dried product was subjected to UV/ozone washing, and the resultant was used as a transparent conductive supporting substrate in the following steps.

Next, the transparent conductive supporting substrate was placed in a vacuum chamber and each layer shown in Table 2 below was formed by employing a vacuum deposition method based on resistance heating in the vacuum chamber having a degree of vacuum of 10⁻⁴ Pa.

TABLE 2

| | | Thickness |
|---|---|---|
| | Constituent material | [nm] |
| First layer | First organic semiconductor | 20 |
| | material: Compound 1 | |
| | Transition metal oxide: MoO₃ | |
| | (The deposition rate was adjusted | |
| | so that the layer contained 5 vol % | |
| | of MoO₃ in itself.) | |
| Second layer | Compound 2 | 10 |
| Emission layer | Host: Compound 3 | 20 |
| | Guest: Compound 4 | |
| | (The deposition rate was adjusted | |
| | so that the layer contained 1 vol % | |
| | of Compound 4 in itself.) | |
| Hole-blocking layer | Compound 5 | 10 |
| Electron transport | Compound 6 | 30 |
| layer | | |
| Electron-injecting | Cesium carbonate | 1 |
| layer | | |
| Cathode | Ag | 29 |

Next, Compound 7 was formed into a film on the cathode 26 to form the capping layer 30. At this time, the thickness of the capping layer was 70 nm. Finally, the organic light-emitting device was sealed in a glove box in a nitrogen atmosphere by bonding a sealing glass containing a desiccant and the film-formed surface of the glass substrate with an epoxy resin adhesive. Thus, the organic light-emitting device was obtained.

The application of a current to the resultant device was able to cause light to exit from each of a substrate side and a cathode side. In addition, the resultant organic light-emitting device was evaluated for its characteristics (a current efficiency (cd/A), voltage (V), and power efficiency (lm/W) at a current density of 25 mA/cm²). Table 3 shows the results. It is to be noted that the term “efficiency” as used in this example refers to the sum of efficiencies obtained on the substrate side and the cathode side.

### Example 2

An organic light-emitting device was produced by the same method as that of Example 1 with the exception that Compound 8 was used instead of Compound 1 upon formation of the first layer in Example 1. It is to be noted that in this example, Compound 8 used as the first organic semiconductor material has a lower refractive index and a larger ionization potential than those of Compound 2 as the second organic semiconductor material.

The resultant organic light-emitting device was measured and evaluated for its characteristics by the same methods as those of Example 1. Table 3 shows the results.

### Comparative Example 1

An organic light-emitting device was produced by the same method as that of Example 1 with the exception that Compound 7 was used instead of Compound 1 upon formation of the first layer in Example 1.

The resultant organic light-emitting device was measured and evaluated for its characteristics by the same methods as those of Example 1. Table 3 shows the results.

### Comparative Example 2

An organic light-emitting device was produced by the same method as that of Example 1 with the exception that Compound 9 was used instead of Compound 1 upon formation of the first layer in Example 1.

The resultant organic light-emitting device was measured and evaluated for its characteristics by the same methods as those of Example 1. Table 3 shows the results.

### Comparative Example 3

An organic light-emitting device was produced by the same method as that of Example 1 with the exception that only Compound 1 was formed into a film to form the first layer upon formation of the first layer in Example 1.

The resultant organic light-emitting device was measured and evaluated for its characteristics by the same methods as those of Example 1. Table 3 shows the results.

### Comparative Example 4

An organic light-emitting device was produced by the same method as that of Example 2 with the exception that only Compound 8 was formed into a film to form the first layer upon formation of the first layer in Example 2.

The resultant organic light-emitting device was measured and evaluated for its characteristics by the same methods as those of Example 1. Table 3 shows the results.

TABLE 3

| | Mixed layer (first layer) | | At 25 mA/cm² | | | |
|---|---|---|---|---|---|---|
| | First organic | Transition | | Current | Power | Power |
| | semiconductor | metal | Voltage | efficiency | efficiency | efficiency |
| | material | oxide | (V) | (cd/A) | (lm/W) | ratio |
| Example 1 | Compound 1 | MoO₃ | 3.98 | 9.76 | 7.7 | 1.94 |
| Example 2 | Compound 8 | MoO₃ | 4.01 | 9.49 | 7.43 | 1.88 |
| Comparative | Compound 7 | MoO₃ | 4.41 | 5.57 | 3.96 | 1 |
| Example 1 | | | | | | |
| Comparative | Compound 9 | MoO₃ | 4.64 | 5.74 | 3.89 | 0.98 |
| Example 2 | | | | | | |
| Comparative | Compound 1 | None | 8.35 | 6.72 | 2.53 | 0.33 |
| Example 3 | | | | | | |
| Comparative | Compound 8 | None | 11.63 | No light | — | — |
| Example 4 | | | | emission | | |

Table 3 above showed that the organic light-emitting devices of Examples (Example 1 and Example 2) were improved in efficiency and reduced in drive voltage as compared to the organic light-emitting devices of Comparative Examples. It is probably because of an improvement in light extraction efficiency by the first layer having a lower refractive index than that of the second layer that the organic light-emitting devices of Examples (Example 1 and Example 2) are improved in efficiency as shown in Table 3. In addition, it is because the requirement concerning the ionization potentials of the respective constituent materials for the first layer and the second layer (the ionization potential of the first organic semiconductor material is larger than that of the second organic semiconductor material) is satisfied that the drive voltages of the organic light-emitting devices of the examples are low. Specifically, the organic light-emitting devices of Examples were each improved in power efficiency ratio by a factor of about 1.9 as compared to the organic light-emitting device of Comparative Example 1.

The foregoing is also applicable to the case where Comparative Example 1 is compared to Comparative Example 2. The drive voltage of the organic light-emitting device of Comparative Example 2 that did not satisfy the requirement concerning the ionization potentials (the ionization potential of the first organic semiconductor material was larger than that of the second organic semiconductor material) was higher than that of the organic light-emitting device of Comparative Example 1. In addition, the organic light-emitting device of Comparative Example 2 was improved in current efficiency as compared to the organic light-emitting device of Comparative Example 1, but its power efficiency was smaller than that of the organic light-emitting device of Comparative Example 1 in association with the increase of the voltage.

In addition, as can be seen from Comparative Examples 3 and 4, the drive voltage of an organic light-emitting device in which the first layer did not contain a transition metal oxide (such as MoO₃) became remarkably high and its power efficiency degraded as compared to that of a related-art device.

According to the present invention, it is possible to provide the organic light-emitting device having high efficiency and capable of being driven at a low voltage. Accordingly, the organic light-emitting device of the present invention is reduced in power consumption than before. Therefore, the application of the organic light-emitting device of the present invention can reduce the power consumption of electronic equipment such as a light-emitting apparatus.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2013-140899, filed Jul. 4, 2013 and No. 2014-132724, filed Jun. 27, 2014, which are hereby incorporated by reference herein in their entirety.

What is claimed is:

1. An organic light-emitting device, comprising:
an anode;
a cathode;
an emission layer between the anode and the cathode;
a first layer comprising a first compound and a transition metal oxide; and
a second layer comprising a second compound,
the first layer and the second layer being formed between the anode and the emission layer, the second layer being in contact with the first layer at an interface on an anode side,
wherein:
the first compound comprises a compound having a π-conjugated structure and free of a transition metal oxide;
the second compound comprises a compound free of a transition metal oxide; and
a refractive index of the first compound is less than 1.6.

2. The organic light-emitting device according to claim 1, wherein an ionization potential of the first compound is equal to or larger than an ionization potential of the second compound.

3. The organic light-emitting device according to claim 1, wherein the transition metal oxide comprises molybdenum oxide.

4. A display apparatus, comprising multiple pixels, wherein at least part of the multiple pixels each comprise the organic light-emitting device according to claim 1 and an active device connected to the organic light-emitting device.

5. An image information-processing apparatus, comprising:
an input portion for inputting image information; and
a display portion for displaying an image,
wherein the display portion comprises the display apparatus according to claim 4.

6. A lighting apparatus, comprising:
the organic light-emitting device according to claim 1; and
an AC/DC converter circuit for supplying a drive voltage to the organic light-emitting device.

7. An image-forming apparatus, comprising:
a photosensitive member;
a charging portion for charging a surface of the photosensitive member;
an exposing portion for exposing the photosensitive member; and
a developing portion for developing an electrostatic latent image on the surface of the photosensitive member,
wherein the exposing portion comprises the organic light-emitting device according to claim 1.

8. An exposing apparatus for exposing a photosensitive member, comprising a plurality of the organic light-emitting devices according to claim 1, wherein the plurality of the organic light-emitting devices are placed in a line.
